(19) United States
(12) Patent Application Publication
(10) Pub. No.: US 2006/0187980 A1
(43) Pub. Date: Aug. 24, 2006

(54) Thin laser module

(76) Inventor: Yun-Yuan Yeh, ChungLi (TW)

Correspondence Address: Troxell Law Office PLLC;ONE SKYLINE PLACE, SUITE 1404, 5205 LEESBURG PIKE, FALLS CHURCH, VA, 22041, US

(21) Appl. No.: 11/263,896

(22) Filed: Nov. 2, 2005

(30) Foreign Application Priority Data
Feb. 18, 2005 (TW) 094202671

(51) Int. Cl. H01S 3/04; H01S 3/00; H01L 33/00; H01L 29/22; H01L 29/24

(52) U.S. Cl. 372/34; 372/38.1; 257/99; 257/100

(57) ABSTRACT

A thin laser module comprises a casing having a light emitting window on one side; a circuit board installed in the casing for containing components; a laser chip installed on the circuit board for emitting a primary laser and a secondary laser; a photodiode (PD) packaged by surface mount technology and installed on the circuit board and disposed at a side of the laser chip for receiving the secondary laser and producing a current; a control circuit installed on the circuit board and coupled to the photodiode for receiving the current to execute an automatic power control; and a lens installed in the casing for receiving the primary laser emitted from the laser chip and modulating the primary laser into parallel beams and transmitting the beams out from the light emitting window.

### BACKGROUND OF THE INVENTION

1. Field of the Invention

The present invention relates to a thin laser module, and more particularly to a thin laser module that installs a photodiode onto a circuit board by the surface mount technology and a light receiving surface faces the beam for receiving more lights to control the stability of the control circuit and provide a more stable light transmitting power.

2. Description of the Related Art

In general, a prior art laser module directly fixes a photodiode chip without being packaged onto a printed circuit board (PCB) by a silver paste. If power is connected, the laser chip will emit a primary laser beam and a secondary laser beam; wherein the primary laser beam is the main beam emitting forward, and the laser beam passes through a non-spherical lens to change the laser beam into parallel beams and serve as an indicator or a marker, and the secondary laser beam is emitted backward for the photodiode chip to receive and produce a current fed back to an automatic power control circuit. However, the foregoing prior art laser module structure produces less feedback current since the light receiving surface of the photodiode chip does not face the beam directly. Therefore, it is necessary to add other optical devices, which will make the structure more complicated and the cost higher.

### SUMMARY OF THE INVENTION

It is a primary objective of the present invention to provide a thin laser module that installs a photodiode (PD) onto a printed circuit board by the surface mount technology and its light receiving surface faces directly to the light beam for receiving more lights to make a control circuit as well as the light transmitting power more stable.

Another objective of the present invention is to provide a thin laser module that includes a casing, and the upper and lower sections of the casing are hollow, and the casing includes a sliding groove separately disposed on both sides for sliding the printed circuit board to adjust the focus of the beam.

To achieve the foregoing objectives, the thin laser module of the invention comprises a casing having a light emitting window on one side; a circuit board installed in the casing for containing components; a laser chip installed on the circuit board for emitting a primary laser and a secondary laser; a photodiode (PD) packaged by surface mount technology and installed on the circuit board and disposed at a side of the laser chip for receiving the secondary laser and producing a current; a control circuit installed on the circuit board and coupled to the photodiode for receiving the current to execute an automatic power control; and a lens installed in the casing for receiving the primary laser emitted from the laser chip and changing the primary laser into parallel beams and transmitting the parallel beams out of the light emitting window.

To make it easier for our examiner to understand the objective of the invention, its structure, innovative features, and performance, we use a preferred embodiment together with the attached drawings for the detailed description of the invention.

### BRIEF DESCRIPTION OF THE DRAWINGS

FIG. 1 is a schematic exploded view of a thin laser module of the invention;

FIG. 2 is a schematic perspective view of a printed circuit board of the invention;

FIG. 3 is a schematic enlarged view of a photodiode being packaged by the surface mount technology according to the invention;

FIG. 4 is a schematic enlarged view of a casing of the invention;

FIG. 5 is a schematic view of a casing further including a cover according to the invention; and

FIG. 6 is a schematic perspective view of a thin laser module of the invention;

### DETAILED DESCRIPTION OF THE PREFERRED EMBODIMENTS

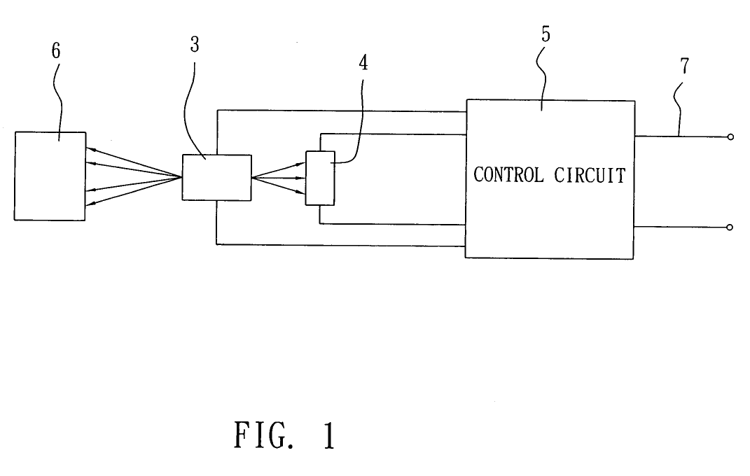

Referring to FIG. 1 for the schematic exploded view of a thin laser module of the present invention, the thin laser module comprises a casing 1, a printed circuit board 2, a laser chip 3, a photodiode (PD) 4, a control circuit 5, and a lens 6.

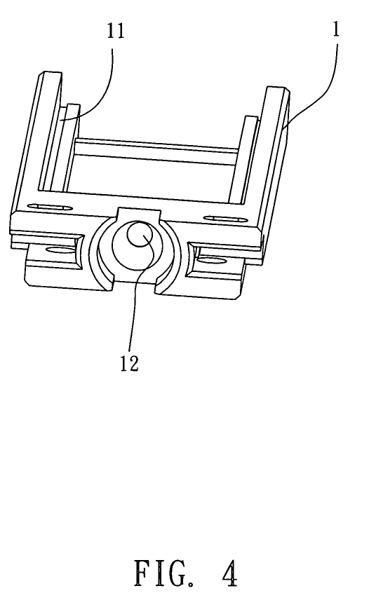

The casing 1 includes hollow upper and lower sections, and a sliding groove 11 (as shown in FIG. 4) for sliding the printed circuit board 2 to adjust the locus of the light beam, and one side including but not limited to the front end of the casing 1 has a light emitting window 12 (as shown in FIG. 4) for emitting the laser beam out, and the casing 1 is preferably made of an insulating material including but not limited to plastics.

The printed circuit board 2 is installed in the casing 1 and capable of sliding along the sliding groove 11 and used for carrying the components such as the laser chip 3, photodiode (PD) 4, and control circuit 5, etc. The printed circuit board 2 further includes a power input end 7 for supplying a direct current power including but not limited to a 3V DC power inputted to the laser chip 3, photodiode (PD) 4 and control circuit 5.

The laser chip 3 is installed at the front end of the printed circuit board 2 for emitting a primary laser and a secondary laser, wherein the primary laser is emitted towards the lens 6 and passed through the lens 6 to convert the laser into parallel beams and then emitted out from the photodiode (PD) 4. The secondary laser is emitted towards the photodiode (PD) 4 and received by the photodiode (PD) 4 to produce a current fed back to the control circuit 5. The anode of the laser chip 3 is attached onto the printed circuit board 2 by a conducting material including but not limited to a silver paste, and the cathode of the laser chip 3 is coupled to the printed circuit board 2 by bounding.

The photodiode (PD) 4 is packaged by the surface mount technology (SMT) and then installed onto the printed circuit board 2 at a side of the laser chip 3. The light receiving surface of the photodiode (PD) 4 faces the secondary laser directly for receiving more lights to produce a current to the control circuit 5.

The control circuit 5 is installed on the printed circuit board 2 and coupled to the photodiode (PDO 4 for receiving the current to execute an automatic power control (APC). One of the technical characteristics of the invention resides on packaging a photodiode chip 41 by a surface mount technology (SMT), so that the light receiving surface of the photodiode (PD) 4 faces the secondary laser directly for receiving more lights, and the feedback current is also larger than the prior art laser module, and thus can make the control circuit 5 and the light transmitting power more stable.

The lens 6 is installed in the casing 1 at a position including but not limited to the front end of the casing 1, and the lens 6 has a surface including but not limited to a non-spherical surface for receiving the primary laser emitted from the laser chip 3 and changing the laser beam into parallel beams and transmitting the beams out from the light emitting window 12. In addition, the structure between the primary laser emitted from the laser chip 3 and the lens 6 is in the form of a polyhedron for removing stray lights to provide a better light form.

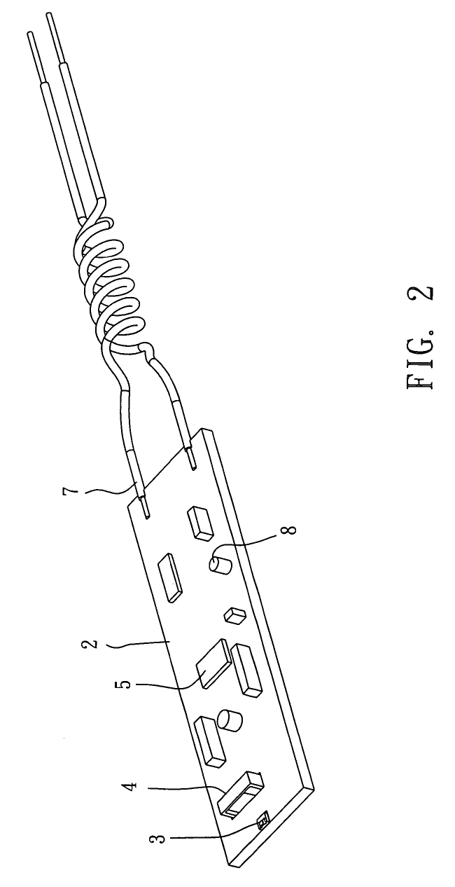

Referring to FIG. 2 for the schematic perspective view of the printed circuit board 2 of the present invention, the printed circuit board 2 includes a laser chip 3, a photodiode (PD) 4, a control circuit 5 and other electronic components 8 (such as resistors, capacitors, and transistors). The laser chip 3 is installed at the front end of the printed circuit board 2. After the power is turned on, the secondary laser beam is emitted backward to the photodiode (PD) 4 to produce a current fed back to the control circuit 5. The control circuit 5 forms a complete automatic power control (APC) circuit with other electronic components (resistors, capacitors, and transistors) for maintaining a constant required light transmitting power.

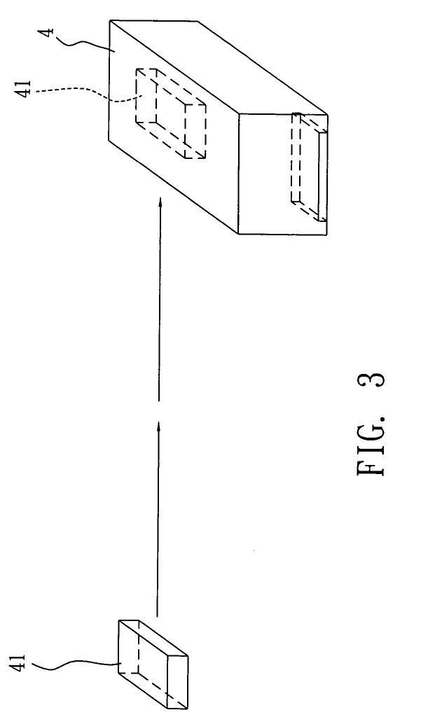

Referring to FIG. 3 for the schematic enlarged view of the photodiode (PD) 4 being packaged by the surface mount technology according to the present invention, the photodiode (PD) chip 41 is packaged by the surface mount technology (SMT) when the photodiode (PD) 4 is assembled, and then the surface mounted photodiode (PD) 4 is soldered onto the printed circuit board 2, and a complete automatic power control (APC) circuit is formed together with other electronic components (resistors, capacitors, and transistors). This method allows the light receiving surface of the photodiode (PD) 4 to face the secondary laser directly for receiving more lights to be fed back to the control circuit 5 and supplying a current flow larger than that of a prior art laser module, and thus making the control circuit 5 and the light transmitting power more stable.

Referring to FIG. 4 for the schematic enlarge view of a casing 1 of the present invention, the casing 1 includes hollow upper and lower sections and a sliding groove 11 separately disposed on both sides of the casing 1 for sliding the printed circuit board 2 to adjust the focus of the primary laser beam. In addition, a position including but not limited to the front end of the casing 1 includes a light emitting window 12 for emitting the laser beam out.

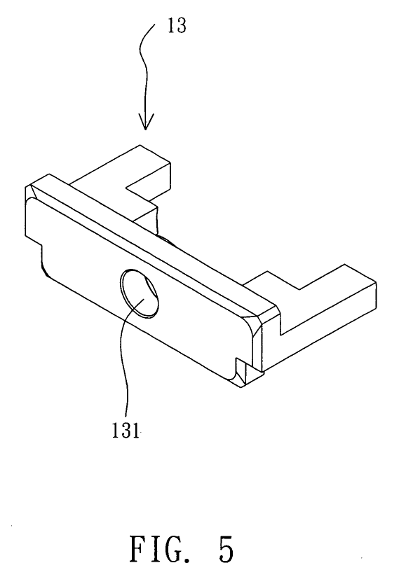

Referring to FIG. 5, the casing 1 of the invention further comprises a cover 13, and the cover 13 includes an opening 131 disposed thereon for connecting the light emitting window 12, so that the primary laser beam can be emitted out from the opening 131 to remove stray lights.

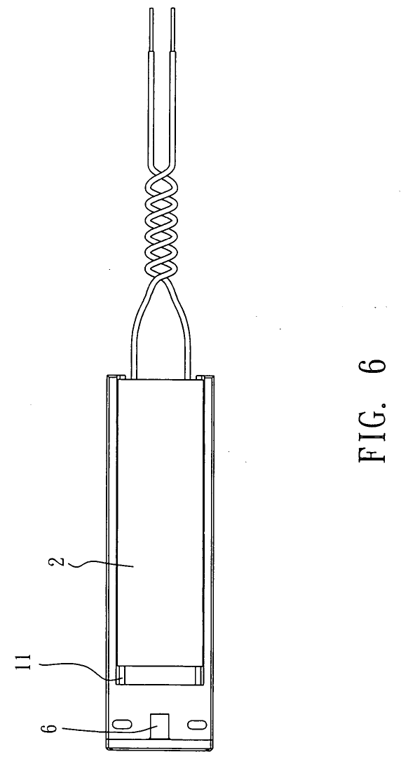

Referring to FIG. 6 for the schematic view of assembling a thin laser module according to the present invention, the laser chip 3, SMT packaged photodiode (PD) 4, and electronic components are all installed on a printed circuit board 1 to constitute a complete electronic control system, when the thin laser module is assembled. The lens 6 is fixed at a position, and then the printed circuit board 2 is placed into the sliding groove 11. The printed circuit board 2 is moved back and forth to adjust the distance between the light emitting point and the lens 6 to achieve the required size of the light spot. After the required light spot is achieved, the printed circuit board 2 is fixed into the casing 1 by a glue to produce the finished goods as shown in FIG. 6.

With the implementation of the present invention, the photodiode (PD) 4 is adhered onto the printed circuit board 2 by the SMT packaging, and the light receiving surface faces the light beam directly to receive more lights and thus making the control circuit as well as the light transmitting power more stable.

While the invention has been described by means of specific embodiments, numerous modifications and variations could be made thereto by those skilled in the art without departing from the scope and spirit of the invention set forth in the claims.

In summation of the above description, the present invention herein enhances the performance than the conventional structure and further complies with the patent application requirements and is submitted to the Patent and Trademark Office for review and granting of the commensurate patent rights.

What is claimed is:

1. A thin laser module, comprising:
a casing, having a light emitting window;
a printed circuit board, installed in said casing for carrying a plurality of components;
a laser chip, installed onto said printed circuit board for transmitting a primary laser and a secondary laser;
a photodiode, being packaged by the surface mount technology and then installed on said printed circuit board and disposed on a side of said laser chip for receiving said secondary laser and producing a current;
a control circuit, installed onto said circuit board and coupled to said photodiode for receiving said current to execute an automatic power control; and
a lens, installed in said casing for receiving said primary laser emitted from said laser chip and adjusting said primary laser into parallel beams and emitting said parallel beams out from said light emitting window.

2. The thin laser module of claim 1, wherein said casing includes hollow upper and lower sections, and a sliding groove disposed separately on both sides of said casing for sliding said printed circuit board thereon for adjusting the focus of said light beam.

3. The thin laser module of claim 1, wherein said printed circuit board further comprises a power input end for inputting said direct current power.

4. The thin laser module of claim 1, wherein said laser chip has a pole attached to said printed circuit board by a conducting material and the other pole coupled to said printed circuit board by bounding.

5. The thin laser module of claim 4, wherein said conducting material is a silver paste coupled to an anode of said laser chip.

6. The thin laser module of claim 1, wherein said casing is made of an insulating material, preferably plastics.

7. The thin laser module of claim 1, wherein said photodiode has a light receiving surface directly facing said secondary laser for receiving more lights.

8. The thin laser module of claim 7, wherein said lens is a non-spherical lens.

9. The thin laser module of claim 1, wherein the structure between said primary laser emitted from said laser chip and said lens is in the form of a polyhedron for removing stray lights to provide a better transmitting light form.

10. The thin laser module of claim 2, wherein said casing further comprises a cover at the front end of said casing and said cover has an opening thereon to be connected to said light emitting window, so that said primary laser is emitted from said opening for removing stray lights.
